(19) United States
(12) Patent Application Publication
(10) Pub. No.: US 2023/0339745 A1
(43) Pub. Date: Oct. 26, 2023

(54) METHOD FOR MANUFACTURING A MICROMECHANICAL SENSOR

(71) Applicant: Robert Bosch GmbH, Stuttgart (DE)

(72) Inventors: Heribert Weber, Nuertingen (DE); Andreas Scheurle, Leonberg (DE); Christoph Hermes, Kirchentellinsfurt (DE); Peter Schmollngruber, Aidlingen (DE); Thomas Friedrich, Moessingen-Oeschingen (DE)

(21) Appl. No.: 17/792,171

(22) PCT Filed: Mar. 22, 2021
(86) PCT No.: PCT/EP2021/057209

§ 371 Date: Jul. 12, 2022

(30) Foreign Application Priority Data
Mar. 26, 2020 (DE) 10 2020 203 906.2

(51) Int. Cl. B81C 1/00; B81B 3/00

(52) U.S. Cl. CPC B81C 1/00523; B81B 3/0024

(57) ABSTRACT

A method for manufacturing a micromechanical sensor. The method includes: applying a first oxide sacrificial layer onto a substrate; removing material of the substrate through openings in the first oxide sacrificial layer; closing the openings in the first oxide sacrificial layer by applying a second oxide sacrificial layer; forming a sensing area on a carrier structure, the sensing area and the carrier structure being formed on the oxide sacrificial layers and the sensing area and/or the carrier structure being connected to the substrate via at least one attachment area, which forms a flexible structure; and at least partially removing the oxide sacrificial layers between the carrier structure and the substrate with the aid of an etching process.

### FIELD

The present invention relates to a method for manufacturing a micromechanical sensor. The present invention further relates to a micromechanical sensor.

### BACKGROUND INFORMATION

In surface micromechanics (SMM), there is invariably the requirement of having to remove sacrificial layers from under large-surface areas. If these areas are unable to be structured in such a way as to be extensively permeated by an etching medium in order, for example, to be able to keep paths for removing a sacrificial layer short, a sacrificial layer must be etched starting from the outermost edges of the area/of the structure. This requires a very long etching time, which may result in higher costs. For this reason, there are various approaches for implementing in a targeted manner channels in the area of a sacrificial layer, with the aid of which the etching medium may be rapidly distributed in the area and as a result significantly shorter etching times may be implemented.
German Patent Application No. DE 10 2013 213 065 B4 describes a mechanical component and a manufacturing method for a micromechanical component.
German Patent Application No. DE 10 2013 222 664 A1 describes a micromechanical structure and a method for manufacturing a micromechanical structure.

### SUMMARY

It is an object of the present invention to provide an improved method for manufacturing a micromechanical sensor.

The object may achieved according to one first aspect of the present invention. In accordance with an example embodiment of the present invention, the method for manufacturing a micromechanical sensor include the following steps:
applying a first oxide sacrificial layer onto a substrate;
removing material of the substrate through openings in the first oxide sacrificial layer;
closing the openings in the first oxide sacrificial layer;
forming a sensing area on a carrier structure, the sensing area and the carrier structure being formed on the oxide sacrificial layers and the sensing area and/or the carrier structure being connected to the substrate via at least one attachment area, which forms a flexible structure; and
at least partially removing the oxide sacrificial layers between the carrier structure and the substrate with the aid of an etching process.

In this way, a sensing area is provided on a carrier structure, which is mechanically decoupled or separated from the underlying substrate, for example, from a silicon substrate (Si substrate) and is connected on the front side at only a few points to the Si substrate. This allows for the creation of a stress-decoupled sensing area with the aid of a sacrificial oxide removed in a large area. A spacing between a carrier structure with the sensing area formed thereon and a support structure is advantageously variable via layer thicknesses. As a result, a stress-related decoupled micromechanical sensor may be manufactured in this way. As a result, a sensing area of a micromechanical sensor (which is conventionally produced on a silicon wafer (Si wafer or also Si substrate) without stress decoupling), is produced according to the present invention on the carrier structure. This means that the complete manufacturing process of a sensor is transferred from a Si wafer surface to the surface of a carrier structure, which makes a stress decoupling possible.

According to one second aspect of the present invention, the object may be achieved with a micromechanical sensor. In accordance with an example embodiment of the present invention, the micromechanical sensor includes:
a carrier structure including a sensing area formed on a carrier structure; the carrier structure being spaced apart at least partially from the substrate downwardly and being attached laterally at least in sections to the substrate.

Preferred refinements of the method are disclosed herein.

In one advantageous refinement of the method of the present invention, trenches and/or trench structures are formed in the substrate for removing the oxide sacrificial layers between the carrier structure and the substrate. In this way, structures are provided in the substrate for distributing etching gas, which make it possible to rapidly distribute an etching gas over a large area. In this way, the release of the carrier structure may be achieved in a simple manner.

In one further advantageous refinement of the method of the present invention, support structures in the form of trenches and/or the trench structures in the substrate are filled with a first oxide sacrificial layer and are used in the further manufacturing process for supporting the carrier structure. In this way, it is possible to carry out a subsequently implemented layer structure in an even, low-deformation and mechanically stable manner, as a result of which it is possible to provide large-area carrier structures, below which silicon may be partially or else also extensively removed for producing etching channels.

In one further advantageous refinement of the method of the present invention, the etching process for producing trenches and/or trench structures as etching channels and/or support structures for supporting a carrier structure in the substrate is isotropic or anisotropic in design. The shape of the trenches may be easily manipulated as a result.

In one further advantageous refinement of the method of the present invention, to form the trenches and/or trench structures, a partial removal of the substrate below a first oxide sacrificial layer takes place through the openings in the first oxide sacrificial layer and the openings in the first oxide sacrificial layer are closed by applying a second oxide sacrificial layer. In this way, a further variant for creating the substructure below the carrier structure is provided.

In one further advantageous refinement of the method of to present invention, nubs on the carrier structure oriented toward the substrate and/or nubs formed on the substrate are formed. As a result, a supporting function in the layer structure of the sensor element is implemented on the one hand, on the other hand, this may prevent the carrier structure from “sticking” to the subsurface in the event of shocks (for example, due to electrostatic forces). The nub height may be easily varied by an adjustment of an etching depth.

In one further advantageous refinement of the method of the present invention, pillars are formed on the carrier structure oriented toward the substrate. As a result, an alternative support structure for the carrier structure is provided.

In one further advantageous refinement of the method of the present invention, the pillars are connected to the substrate or are formed spaced apart from the substrate. In the different ways of forming the pillars cited, it is possible to implement different support concepts for the carrier structure.

In one further advantageous refinement of the method of the present invention, a first polysilicon layer having a defined layer thickness is formed on the oxide sacrificial layers.

In one further advantageous refinement of the method of the present invention, a second, fast-growing polysilicon layer having a defined layer thickness is formed on a first polysilicon layer. As a result, a greater/higher total layer thickness for a carrier structure may be advantageously provided in a simple manner.

In one further advantageous refinement of the method of the present invention, an attachment area of the carrier structure is formed at least partially and/or in areas on the substrate in a monocrystalline manner. Circuit components may be advantageously formed in the monocrystalline areas.

In one further advantageous refinement of the method of the present invention, the fact that an attachment area of the carrier structure is formed on the substrate in a polycrystalline manner.

In one further advantageous refinement of the method of the present invention, electrical circuit components, which are attached with strip conductors at the sensing area, are formed in the attachment area. In this way, an electrical attachment of the circuit components at the sensing area may be implemented with strip conductors, which may be guided, for example, via spring structures.

### BRIEF DESCRIPTION OF THE DRAWINGS

The present invention is described in detail below including further features and advantages with reference to multiple figures. Identical or identically functioning elements have the same reference numerals. The figures are intended, in particular, to illustrate the main features of the present invention and are not necessarily implemented true to scale. For the sake of better clarity, it may be provided that not all reference numerals are marked in all figures.

FIGS. 1 through 3A-3D show cross-sectional views of a conventional micromechanical layer structure;

FIGS. 4 through 17 show exemplary views of process stages of a provided method for manufacturing a micromechanical sensor;

FIGS. 18A and 18B shows a top view and a cross-sectional view of a provided micromechanical sensor;

FIG. 19 shows a top view of one further specific embodiment for manufacturing a provided micromechanical sensor;

FIGS. 20 through 40 show exemplary views of process stages of one specific embodiment of a provided method for manufacturing a micromechanical sensor; and

FIG. 41 shows a basic sequence of a method for manufacturing a provided micromechanical sensor.

### DETAILED DESCRIPTION OF EXAMPLE EMBODIMENTS

A main feature of the present invention is, in particular, to provide in a simple manner a stress-decoupled micromechanical sensor or a sensing area of a micromechanical sensor.

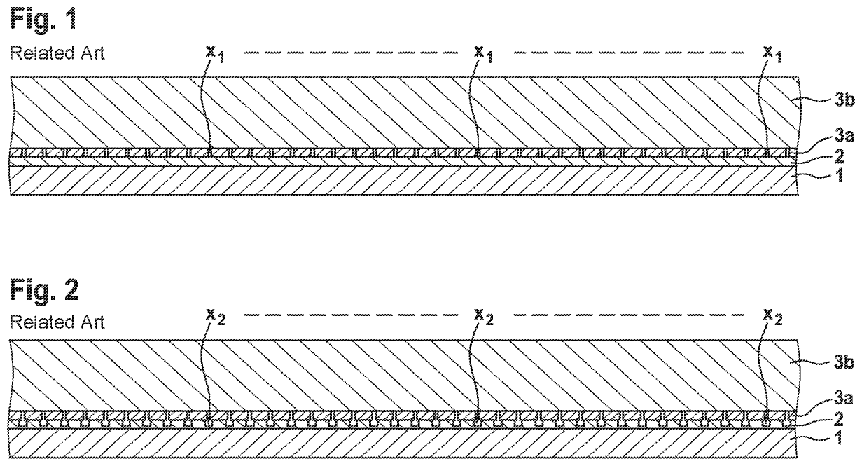

FIG. 1 shows a cross section through a conventional layer structure for providing a stress-decoupled sensing area. A sensing area in this case is understood to mean an area of the micromechanical sensor, in which a conversion of a physical signal (for example, a pressure sensor signal) into an electrical signal takes place. Movable and non-movable structures such as, for example, diaphragms, movable masses, electrodes and/or electrical strip conductors may be embedded in the sensing area in a periphery surrounding the latter, which are necessary for manufacturing, for example, pressure sensors, microphones, acceleration sensors, rotation rate sensors, mass air-flow sensors, gas sensors and the like.

A substrate 1 (Si substrate) is apparent, on which a first oxide sacrificial layer 2 (for example, an SiO₂ sacrificial layer) is situated or deposited. Located on first oxide sacrificial layer 2 is a first polysilicon layer 3a (“polysilicon start layer”) including etching channels x₁, which extend up to oxide layer 2, on which a second polysilicon layer 3b (epitaxial polysilicon, EPI polySi) has been deposited with the aid of a selective silicon deposition in an EPI reactor. The intended result of a selective silicon deposition is that no silicon grows on an oxide surface during a deposition of polysilicon in an EPI reactor.

As a variant thereto, widened etching channels x₂ may optionally also be formed in sacrificial layer 2, as indicated in FIG. 2.

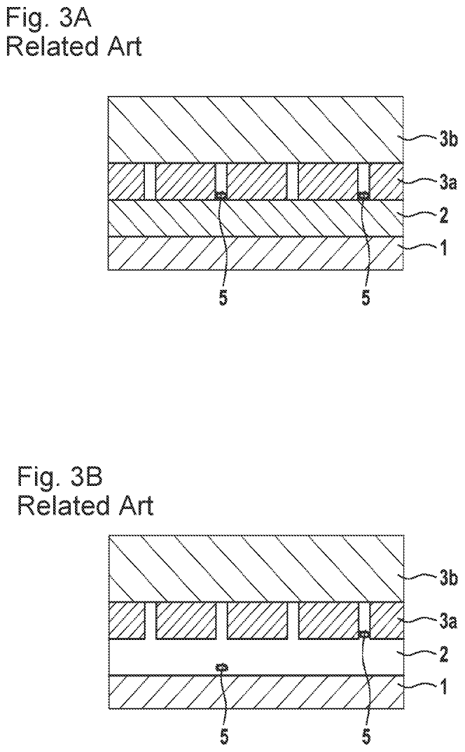

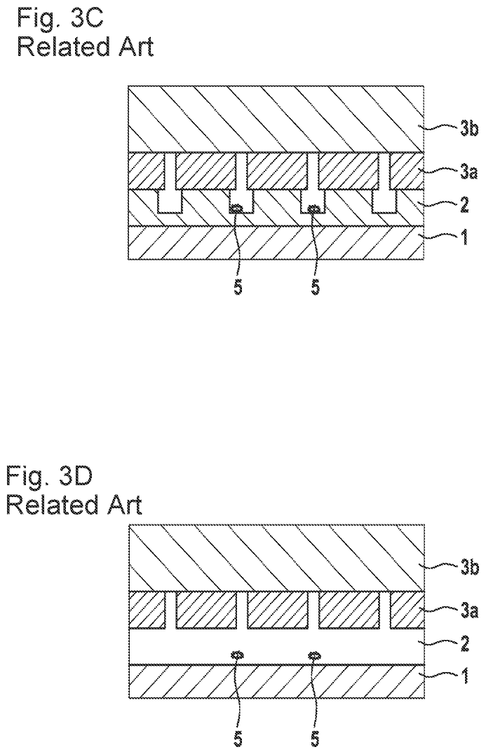

FIGS. 3A-3B show that during the growth of second polysilicon layer 3b, silicon may be deposited at nucleation seeds on oxide surfaces in the etching channels such as, for example, etching residues or particles. If first oxide sacrificial layer 2 is then later removed, freely movable silicon particles 5 may form, as is indicated in FIGS. 3A through 3D.

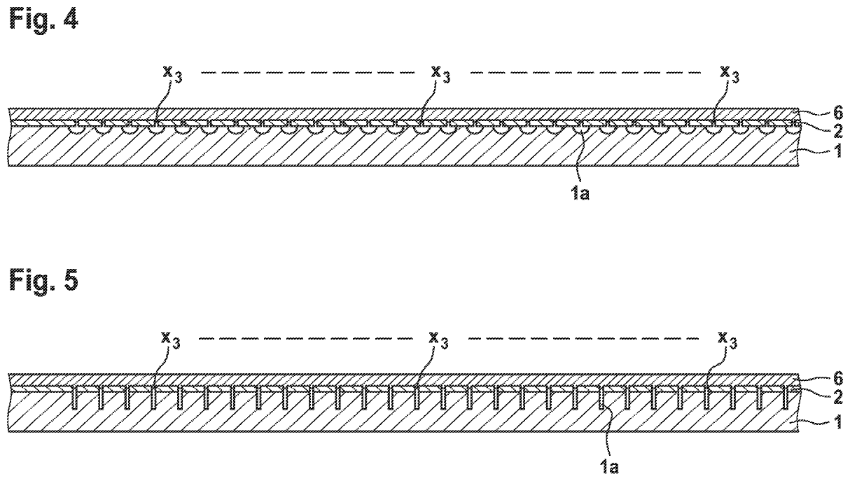

In order to avoid this, a first oxide sacrificial layer 2 in one variant of the provided method as represented in FIG. 4 is initially deposited in at least the area of a micromechanical sensor, in which a separation of a sensing area from substrate 1 is to take place in a later process stage. In a subsequent step, first oxide sacrificial layer 2 is structured with the aid of standard semiconductor methods and substrate 1 is exposed in the resultant openings x₃. In the areas exposed in this manner, silicon in substrate 1 is subsequently removed. This may take place, as indicated in FIG. 4, using an isotropic or, as indicated in FIG. 5, using an anisotropic etching process.

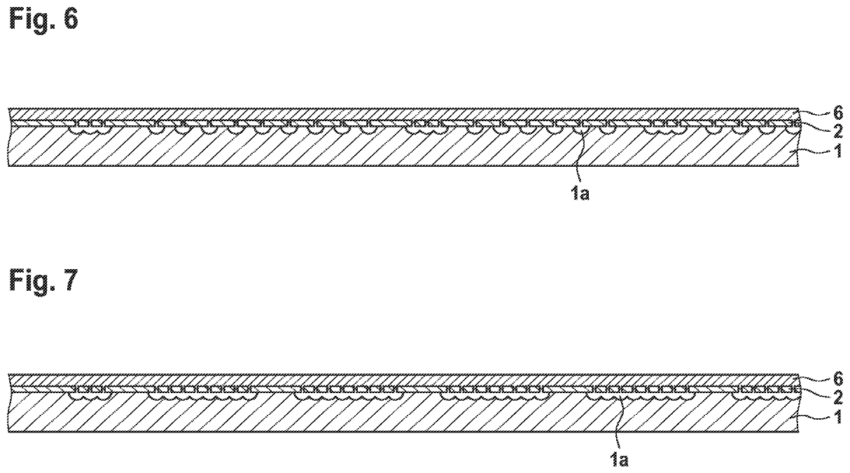

Depending on the spacing of the openings in first oxide sacrificial layer 2, larger as well as laterally expanded and cohesive, silicon-free areas may be produced below first oxide sacrificial layer 2 in the Si substrate when using an isotropic Si etching process. As a result, it is possible, for example, to be able to produce channel structures or trenches 1a with a larger channel cross section, as is apparent in FIG. 6 and FIG. 7, below first oxide sacrificial layer 2. The Si-free areas may, for example, also further be used to produce nub structures from substrate material, which may be used to avoid a sticking on substrate 1 of the sensing area later released from substrate 1.

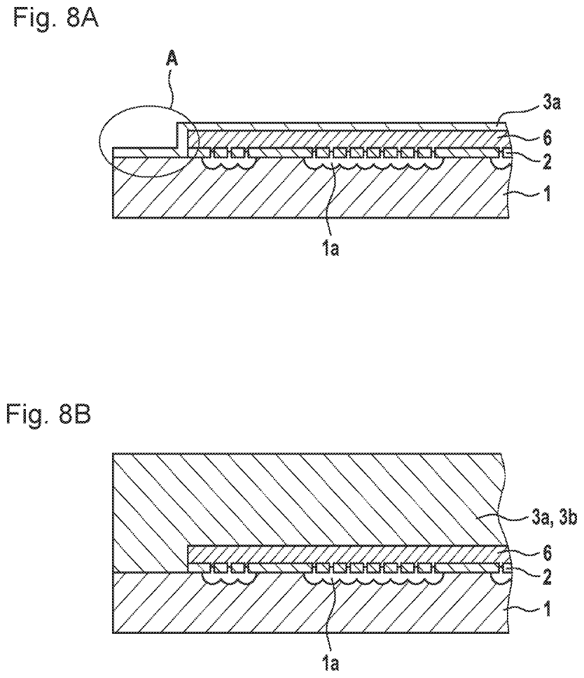

After removal of the silicon in the area of the openings of first oxide sacrificial layer 2, the closure of the openings takes place with the aid of a second oxide sacrificial layer 6 (for example, with an SiO₂ sacrificial layer). If SiO₂ is deposited in this case in the structures produced in substrate 1, the former is also removed in a later SiO₂ sacrificial layer etching process, as a result of which advantageously no freely movable particles 5 are formed. The maximum width of the openings in first oxide sacrificial layer 2 is decisive in this case for the required minimum thickness of second oxide sacrificial layer 6, which is necessary for a secure closure of the openings in first oxide sacrificial layer 2. The smaller the maximum width of the openings in first oxide sacrificial layer 2 is, the smaller is the minimum required layer thickness of second oxide sacrificial layer 6 that may be selected. A first polysilicon layer 3a, on which a second polysilicon layer 3b may further be deposited, is subsequently deposited onto second oxide sacrificial layer 6, first polysilicon layer 3a being capable of being used as a start layer for growing the second polysilicon layer 3b in an EPI reactor. If the two oxide sacrificial layers 2, 6 are structured prior to the deposition of first and second polysilicon layers 3a, 3b, first polysilicon layer 3a and, optionally, second polysilicon layer 3b may also be deposited on substrate 1 (area A) and form here, for example, fastening points/fastening structures on substrate 1 for the sensing area to be released, as is represented in FIGS. 8A, 8B.

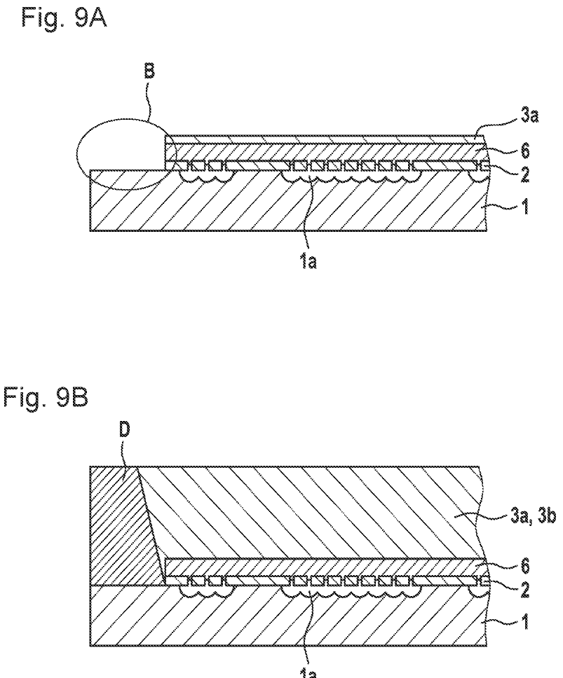

If polysilicon layer 3a is structured together with the two oxide sacrificial layers 2, 6, polycrystalline and monocrystalline Si areas D may be simultaneously produced during the epitaxial Si deposition of subsequent silicon layer 3b. The polycrystalline silicon area are formed in this case on first polysilicon layer 3a and monocrystalline areas D on exposed monocrystalline substrate 1, as indicated in FIGS. 9A and 9B with areas B and D. In the latter case, monocrystalline silicon areas D may now serve as fastening points/fastening structures on substrate 1 for a sensing area later to be released and/or for the further integration of electrical semiconductor circuits. As represented in FIGS. 8B, 9B, a polishing step, chemical mechanical polishing (CMP) may also be carried out after the silicon deposition in order to obtain a planar surface.

A thickness of second polysilicon layer 3b in this case may be as much as approximately 100 μm and more and may be deposited/grown significantly faster in an EPI reactor than, for example, in an LPCVD process (low pressure chemical vapor deposition). As a result, a stable and torsion-resistant backplane in the form of the carrier structure including polysilicon layers 3a, 3b may thereby be provided for the micromechanical sensor.

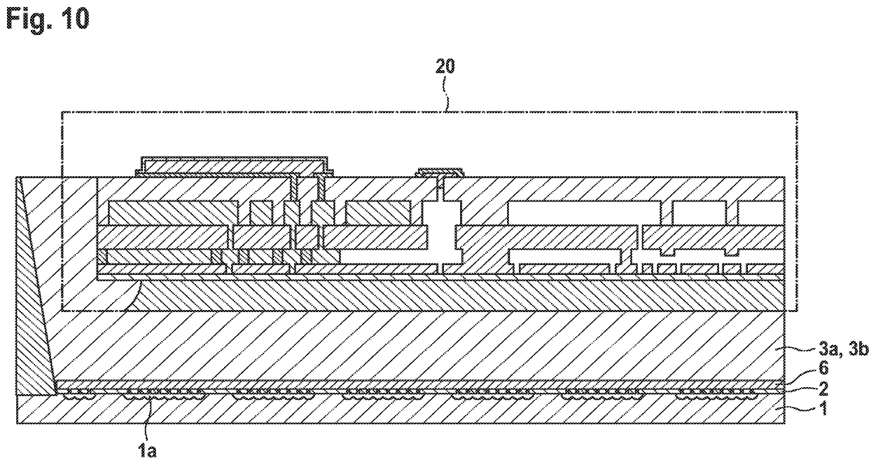

A micromechanical component (for example, in the form of a capacitive pressure sensor) may now be produced on the Si-surface thus prepared. In this component, an area is structurally provided, in which monocrystalline silicon may grow epitaxially on the Si substrate (so-called EPI plug area). If this EPI plug area is now positioned in area B on the Si substrate, which has also been formed in a monocrystalline manner, as represented in FIG. 9B, it is technically possible to be able to produce, for example, a surface micromechanical component, whose sensing area 20 is formed on polycrystalline silicon layers 3a, 3b, which are located on oxide sacrificial layers 2, 6, as represented in FIG. 10 and, in addition, may include monocrystalline area D at the surface.

Further details regarding the procedural production of sensing area 20 on the carrier structure including polysilicon layers 3a, 3b are not further discussed here, since these process steps are conventional.

If in one of the last processing steps an etching access 8 is now produced within sensing area 20 from the surface into the “channel system” below oxide sacrificial layers 2, 6, a rapid etching over a large area of oxide sacrificial layers 2, 6 may take place below carrier structure 3a, 3b of sensing area 20 via this etching access, as a result of which a cavity 16 is formed below carrier structure 3a, 3b on which sensing area 20 is located.

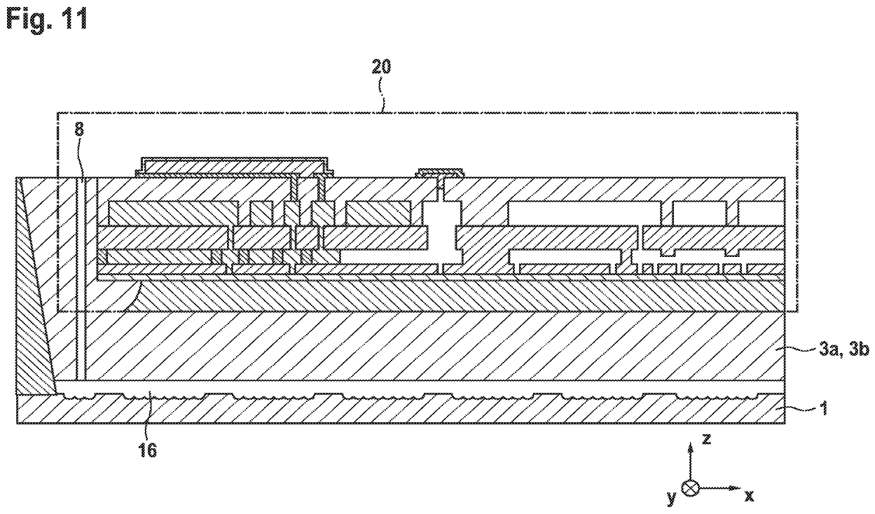

This is visually represented in FIG. 11. Here, for example, an etching access 8 has been produced in the polycrystalline area of the EPI plug with the aid of one or multiple preferably anisotropic plasma etching processes (trenching of silicon and etching SiO₂ or etching of a homogenous or uniform silicon layer in a plasma etching step) and oxide sacrificial layers 2, 6 have been removed through this etching access 8.

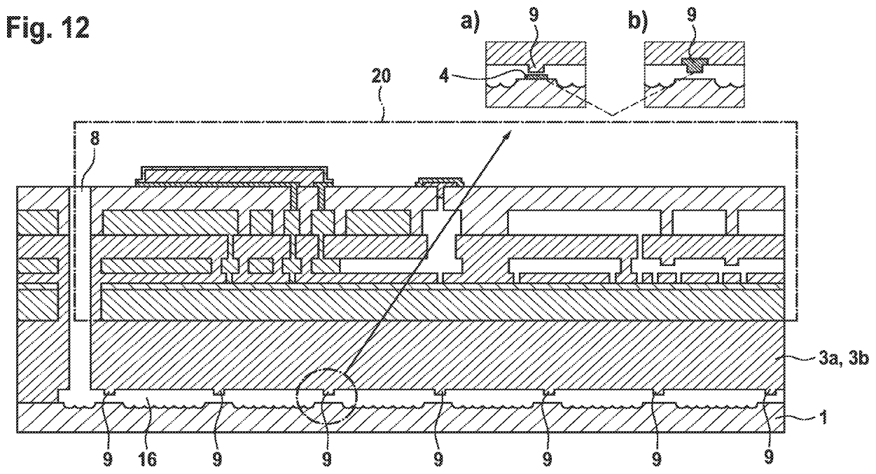

FIG. 12 shows one further example, in which etching access 8 takes place through the layer system in sensing area 20. If oxide sacrificial layers 2, 6 are made of SiO₂, it is expedient to form the edge of etching access 8 from silicon. In this way, the removal also of oxide layers within the layer system in sensing area 20 of the micromechanical component may be advantageously avoided. As is further apparent in FIG. 12, nubs 9 may also be present under released sensing area 20, which are located at the side of carrier structure 10 facing the substrate and in particular situations may impinge on corresponding surfaces at substrate 1.

As a result, sensing area 20 has essentially the same lateral dimensions as carrier structure 3a, 3b situated below. One variant, in which sensing area 20 may also have smaller lateral dimensions than carrier structure 3a, 3b located below, is not represented in the figures.

Nubs 9 may be made of polysilicon or from an electrical insulating material, which possess a high etching resistance to the oxide sacrificial layer etching medium and which has been deposited and optionally structured on second oxide sacrificial layer 6 prior to the deposition of polysilicon layer 3a.

The images a) and b) of FIG. 12 show different variants of nubs 9. In image 12 a), for example, a variant is shown, in which an etch-resistant layer 4 is optionally located in the area of a nub 9 made of polysilicon on a corresponding surface of substrate 1, the material of which possesses a high etch resistance to the oxide sacrificial layer etching medium and is electrically insulating.

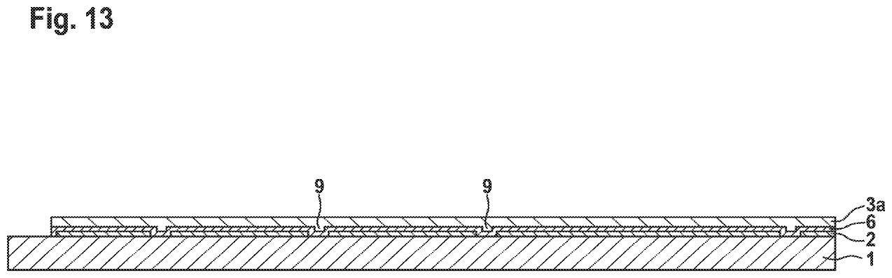

In image 12 b), the variant may be seen, in which nub 9 itself is made of an electrically insulating material, which possesses a high etching resistance to the sacrificial layer etching medium. As is apparent in FIG. 13, nubs 9 may be produced by targeted structurings of the two oxide sacrificial layers 2, 6.

It is also possible to provide an etch-resistant and electrically insulating layer 4 on nub structures at the substrate surface, which may be produced by targeted structuring of first oxide sacrificial layer 2 and targeted etching of substrate 1, as is shown in image 12 a). In this case, the deposition and structuring of this layer would take place prior to the deposition of first oxide sacrificial layer 2.

In accordance with FIG. 12, the distance between carrier structure 3a, 3b on which sensing area 20 is located and substrate 1 may not be defined solely by a corresponding choice of the layer thicknesses of oxide sacrificial layers 2, 6. Instead, the distance may also be increased by etching substrate 1 with the aid of an additional gas phase etching process (for example, with the aid of XeF2).

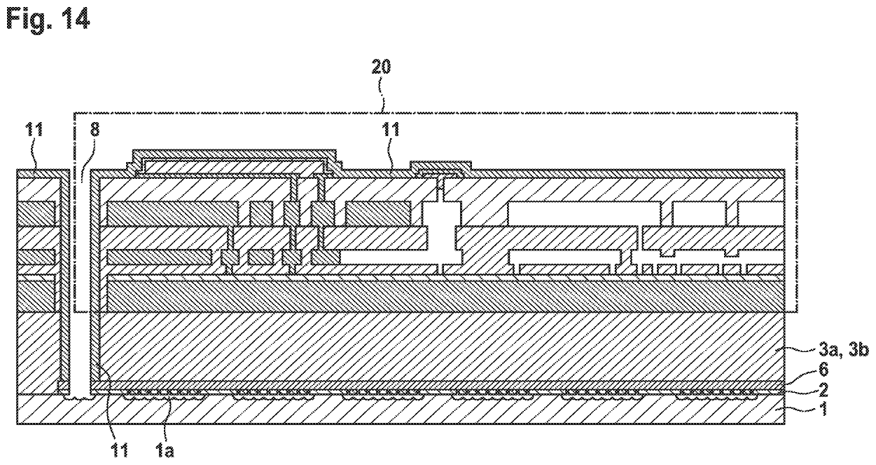

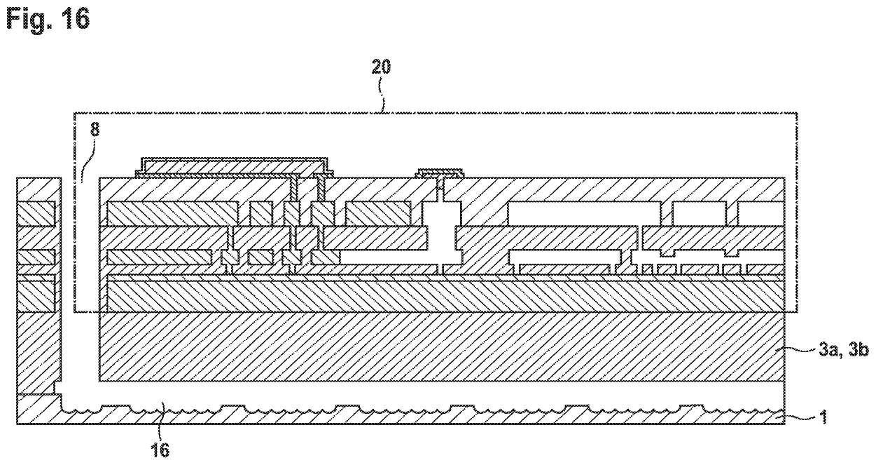

FIG. 14 represents how etching access 8 must be designed for this purpose. So that no unintentional etching attack takes place during the XeF2 etching on exposed Si-surfaces, these surfaces must be protected with an etch-resistant layer 11 such as, for example, SiO₂, which applies also to the area of etching access 8. By selecting a suitable shape and distribution of openings x₃ in first oxide-sacrificial layer 2 a, it may be established how trenches 1a in substrate 1 are formed. In FIG. 14, it is apparent how in this way non-etched areas of substrate 1 also oriented upwardly may be produced, which act as nubs, which is even more clearly apparent in FIG. 16, where the entire sacrificial oxide is etched out. These nubs may advantageously contribute to the surface of carrier structure 3a, 3b exposed in cavity 16 being unable to “stick” to substrate 1 in the presence of strong acceleration forces on the sensor.

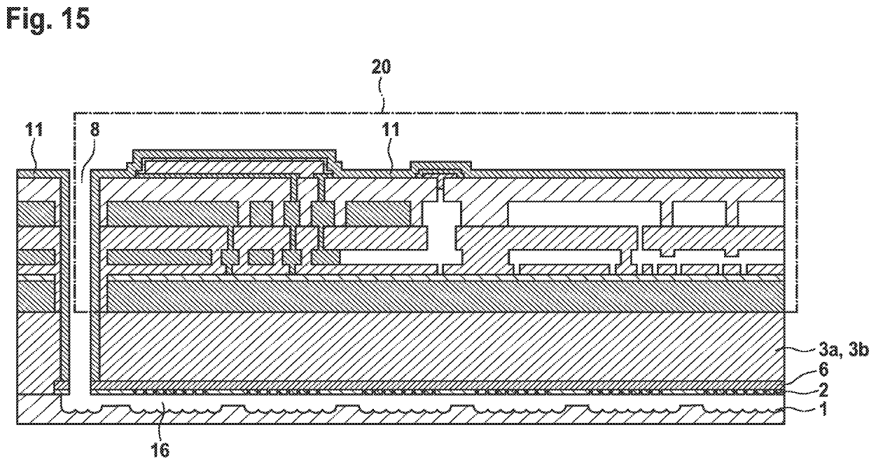

FIG. 15 shows by way of example a stress-decoupled sensing area 20 on a carrier structure 3a, 3b after an XeF2 etching with oxide sacrificial layers 2, 6 still present and etch-resistant (protective) layer 11 still present.

After the etching of substrate 1 below carrier structure 3a, 3b on which sensing area 20 is located, the removal of the SiO₂ protection and sacrificial layers subsequently takes place with the aid of a gas phase etching process (for example, HF gas phase etching process). So that no etching attack is able to take place here on SiO₂ insulation layers between strip conductor planes of the sensing area, a layer made of, for example, silicon and/or silicon-rich silicon nitride, which is etch-resistant to a gas phase etching process, must also be present in an etching access channel 8 behind the walls made of a material 11 etch-resistant to XeF2 such as, for example, SiO₂.

Other structures as well, which possess no etch resistance to the etch gas used (for example, HF vapor), should be protected with a corresponding protective layer, these other structures may also be electrical strip conductors, electrically insulated areas or electrical insulation layers. To be able to avoid electrical short circuits in these cases, the protective layer here must be made of an electrically non-conductive material such as, for example, silicon-rich silicon nitride.

FIG. 16 shows a stress-decoupled sensing area 20 including carrier structure 3a, 3b after an additional HF gas phase etching. With respect to FIG. 11, it is apparent here that the distance between carrier structure 3a, 3b of sensing area 20 and substrate 1 may be additionally increased with the aid of an additional XeF2 gas phase etching process.

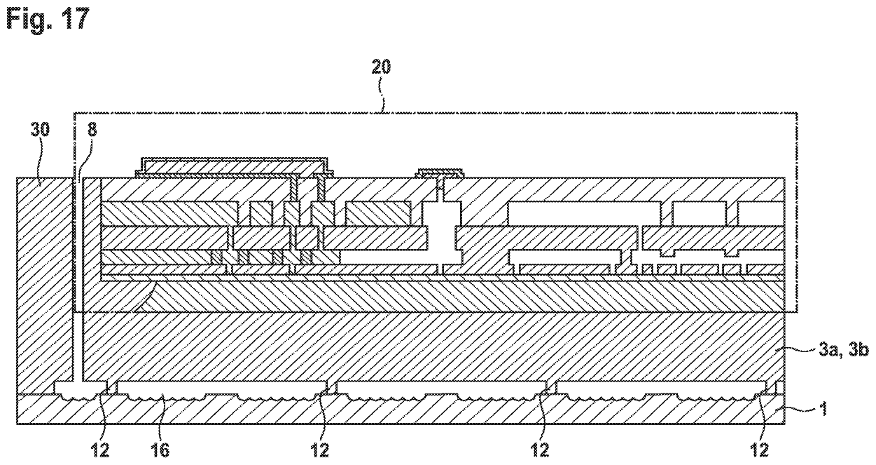

FIG. 17 shows one further variant, in which attachment area 30 of sensing area 20 is formed in a completely polycrystalline manner on the substrate and, after removal of the sacrificial oxide of sensing area 20, is connected via one or multiple columns or pillars 12 connected to substrate 1. For the sake of completeness, it is mentioned here that in the case of the variants described in FIGS. 10 and 11 as well, attachment area may be designed in a completely polycrystalline manner.

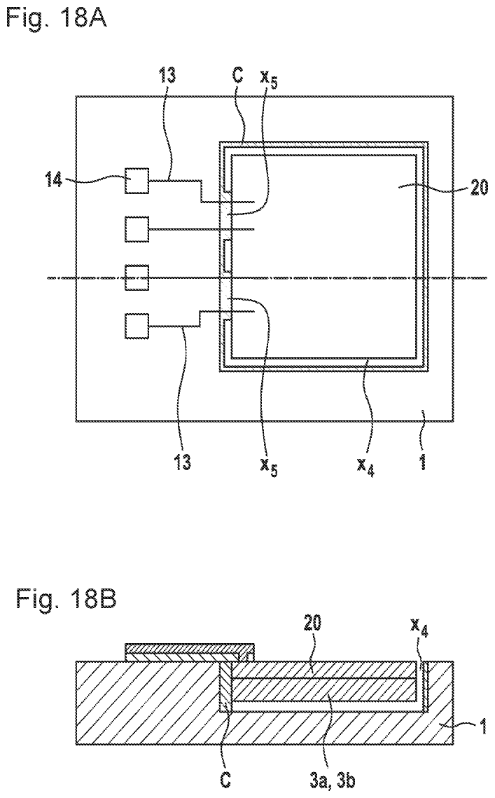

The top view and the corresponding cross-sectional views of FIGS. 18A, 18B show one possibility of how a carrier structure 3a, 3b including a sensing area 20 may be designed stress-decoupled to surrounding substrate 1 and/or to the layer system. In the case shown, carrier structure 3a, 3b including sensing area 20 is fixed on one side at surrounding substrate 1 and/or the layer system, but otherwise formed separately from surrounding silicon substrate 1 and/or the layer system. The lateral separation takes place here by introducing a trench structure x₄ downward to oxide sacrificial layers 2, 6 and to the etching channel system located below, a separation between carrier structure 3a, 3b including sensing area 20 located above and substrate 1 having been achieved by a removal/etching of oxide sacrificial layers 2, 6.

It is further apparent that the production of the trench structure takes place in a polycrystalline Si-area C, which encloses carrier structure 3a, 3b and sensing area 20 which, in turn, is surrounded by monocrystalline silicon. Via the one-sided “fixation x₅” of carried structure 3a, 3b and of sensing area 20 achieved thereby, it is further possible to feed electrical strip conductors 13 from sensing area 20 to the solid ground and to electrically connect these to integrated circuits and bond pads 14. In one further variant, the area enclosing carrier structure 31, 3b and sensing area 20 may be made completely of polycrystalline silicon or else from a circumferential polycrystalline Si area which, in turn, is surrounded by an area in which the same layer sequence is formed on oxide superficial layers 2, 6 as in carrier structure 3a, 3b and sensing area 20.

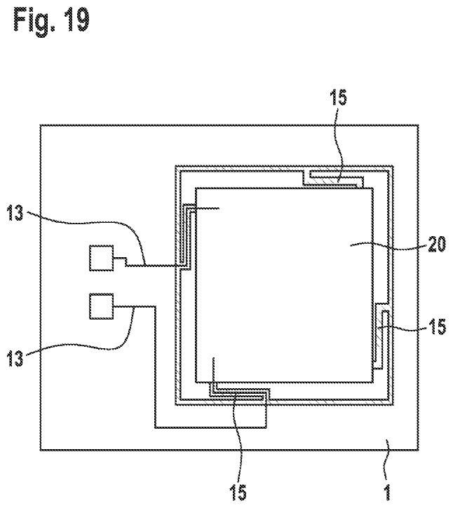

FIGS. 18A, 18B and 19 show examples of springs 15 or strip conductors 13. Further suspension structures not explicitly explained may also be implemented in the manner described.

The top view of FIG. 19 shows one further example, in which carrier structure 3a, 3b including sensing area 20 is connected via flexible structures/springs 15 to the surrounding solid ground. In this case, the etching process for producing trench structure x₄ is also used for producing spring structures 15, which are partially or fully located in the polycrystalline Si area, which encloses carrier structure 3a, 3b and sensing area 20. The electrical connection of structures in sensing area 20 takes place in this example with the aid of electrical strip conductors 13, which are guided via the elastic structures or springs 15 and which may be made of doped polysilicon, of metallic material, of metal silicides, of targeted doped areas in the silicon surface or of combinations thereof.

Polysilicon layers 3a, 3b produced on oxide sacrificial layers 2, 6 serve essentially as a substructure or as a carrier structure for sensors or sensing areas, which are to be/required to be stress-decoupled by an at least partially circumferential trench and by removing oxide sacrificial layers 2, 6 from surrounding substrate 1 and/or from the surrounding layer system. The structure shown has the advantage that it enables both high SiO₂ sacrificial oxide etching rates via etching channels in the silicon substrate as well as a stable, deformation-free subsurface and layer structure, which enables without limitations the use of standard semiconductor processes for producing the desired structures. The possibility of being able to provide areas at the chip surface, which are made of monocrystalline silicon, further allows integrated circuits to be able to be provided. In this way, an integrated OMM pressure sensor chip or inertial sensor chip, for example may be implemented, whose sensing area 20 is formed stress-decoupled to the surrounding substrate.

One further variant for manufacturing a micromechanical sensor 100 is explained in greater detail below with reference to FIGS. 20 through 39.

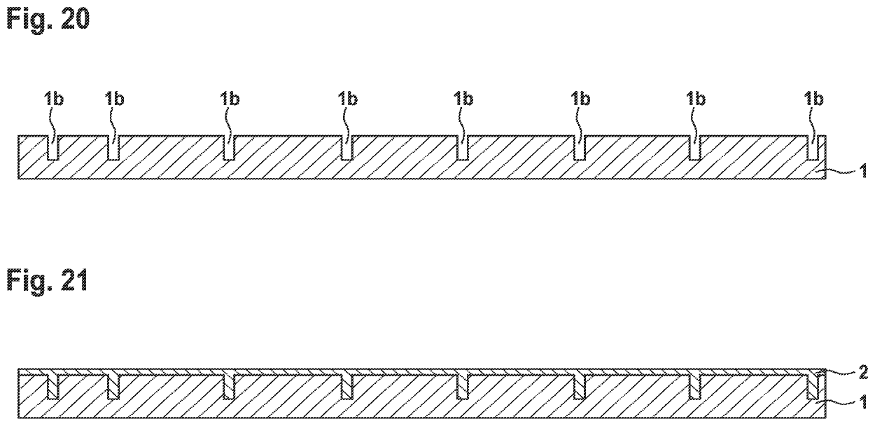

FIG. 20 shows that to increase the distance defined between an area to be released and a substrate 1, trench structures 1b may be introduced into substrate 1, which are subsequently filled with the aid of a first oxide sacrificial layer 2 (for example, silicon oxide layer), as is indicated in FIG. 21. This may take place, for example, by thermal oxidation, deposition of an LPCVD oxide layer or PECVD oxide layer or a TEOS oxide layer or by a combination of these layers. In order to be able to minimize the local stress formed by the filling of trench structures 1b with SiO₂, the form of trench structures 1b may be selected in such a way that the smallest opening width exists at the substrate surface and trench structures 1b widen with increasing trench depth.

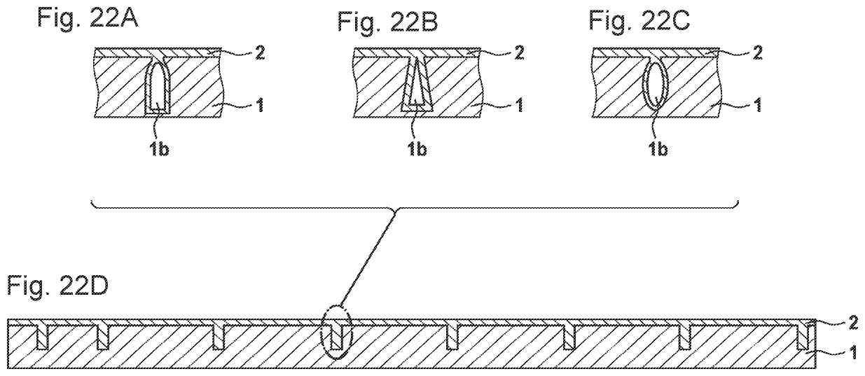

In this way, a trench structure 1b lined with SiO₂ may be produced, which is closed at the substrate surface. The cavity thus produced is used for local stress decoupling and prevents the formation of undesirable cracks in substrate 1. The trench structures 1b in this case may have a bottle-like (FIG. 22A), triangular (FIG. 22B) or bulbous (FIG. 22C) shape. (See FIG. 22D).

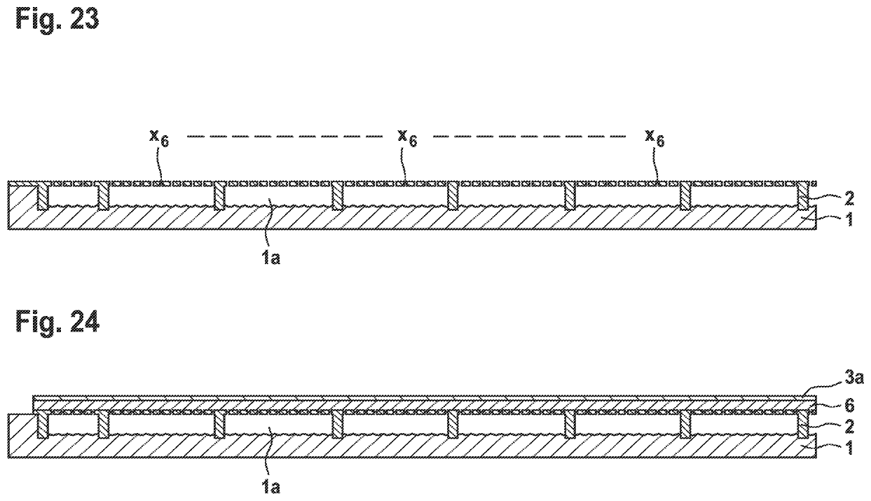

After deposition of first sacrificial oxide layer 2 into trench structures 1b and closure of trench structures 1b by first sacrificial oxide layer 2, openings x₆ are etched into deposited first oxide sacrificial layer 2 outside filled or closed trench structures 1b, through which the underlying silicon is removed with the aid of an isotropic silicon etching process (for example, XeF2 or isotropic plasma etching step), as indicated in FIG. 23. The pillars of first oxide sacrificial layer 2 remaining after the silicon etching process are apparent. The depth of the resultant cavity in this case should be smaller than or equal to the depth of trench structures 1b lined with first oxide sacrificial layer 2, in order to avoid an undercutting of the SiO₂ structures produced thereby. This is important because the SiO₂ structures serve to stabilize the subsurface for the further layer structure of the area to be later released. The SiO₂ structures in this case may have an arbitrary number and shape. In order to obtain a preferably planar first oxide sacrificial layer 2, a superficial planarization step (CMP step) may additionally take place prior to the production of openings x₆ in the first oxide sacrificial layer.

The SiO₂ structures produced in substrate 1 may, when suitably designed, also be used to produce lateral etch stop structures. This has the advantage that the lateral and vertical dimensions of the cavity below the area to be released may be selected or designed independently of one another.

After removal of the silicon through openings x₆ in first oxide sacrificial layer 2, openings x₆ in first oxide sacrificial layer 2 are closed with the aid of a second oxide sacrificial layer 6. After the closure of openings x₆, a first polysilicon layer 3a may further be deposited, which is removed outside the stress decoupled area together with the previously deposited SiO₂ layers, as is represented in FIG. 24. As a result, pillars and optionally lateral etch stop structures made of first oxide sacrificial layer 2 are now formed between substrate 1 and second oxide sacrificial layer 6 with first polysilicon layer 3a deposited thereon, which provide a mechanical stability for the further layer structure and are surrounded at least partially by closed cavities.

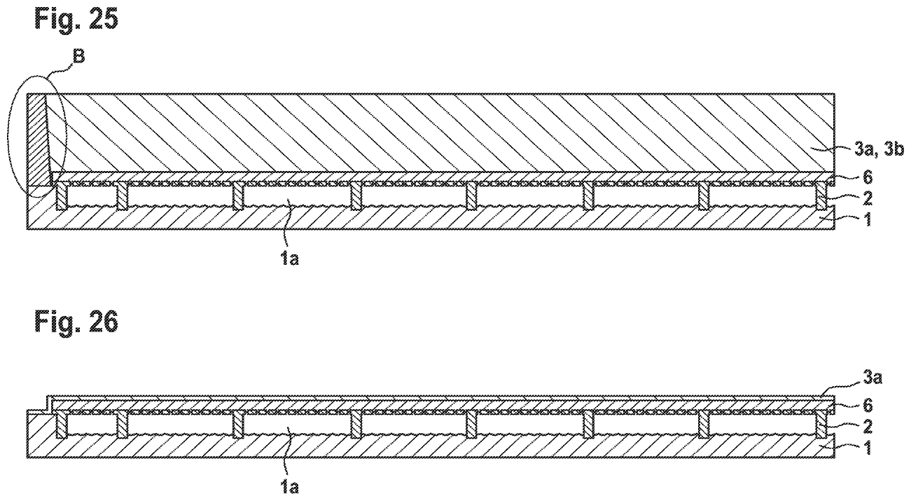

If a second silicon layer is now deposited/grown on the surface thus prepared in an epitaxial reactor (EPI reactor), as represented in FIG. 25, then this layer grows in a polycrystalline manner in the areas in which first polysilicon layer 3a is present, the second polysilicon layer 3b being formed and in a monocrystalline manner (area B) in the areas in which substrate 1 has been exposed.

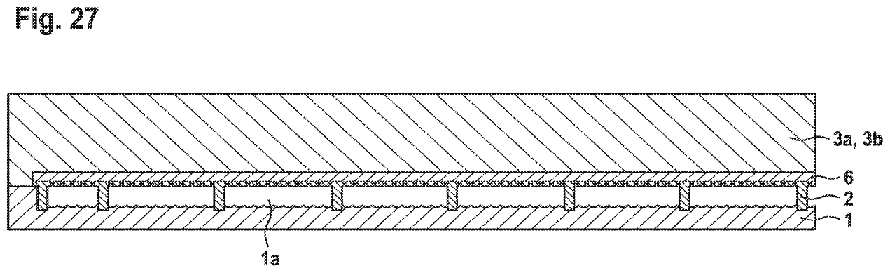

If, however, only sacrificial oxide layers 2, 6 are structured and first polysilicon layer 3a is deposited extensively on the entire wafer, as represented in FIG. 26, then polycrystalline silicon grows over the entire surface on the wafer during a silicon deposition in an EPI reactor, as is apparent in FIG. 27 and corresponding to area A in FIG. 8A. Second polysilicon layer 3b grown in an EPI reactor and first polysilicon layer 3a referred to in the technical language as “start layer” in this context serve in the area that is to be stress-decoupled as carrier structure 3a, 3b for further layers, with which a sensing area 20 may be implemented, whereas the area in which silicon is grown in a monocrystalline manner may be utilized for the integration of electronic circuit components.

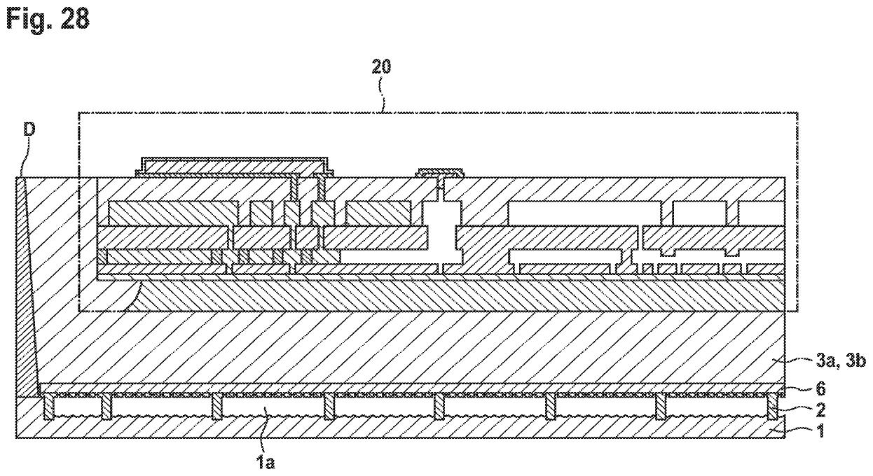

FIG. 28 shows a cross section including a sensing area 20 and monocrystalline area D, in which electronic circuit components (not represented) may be situated, which may be electrically connected to sensing area 20.

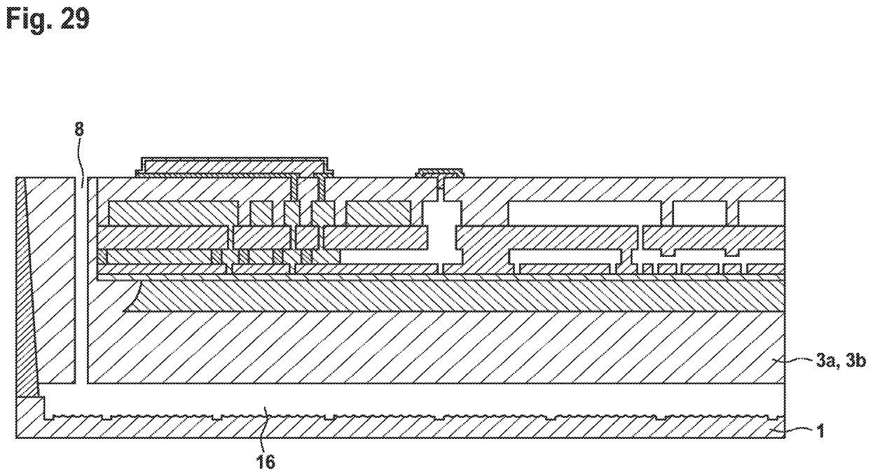

After implementation of all necessary process steps for implementing sensing area 20, etching accesses 8 may be implemented at one or multiple positions of the surface through the existing layer system to cavity 16, which is located below and pervaded with SiO₂ structures. Since the SiO₂ layers within cavity 16 are to be removed through these etching channels 8 with the aid of wet-chemical or gaseous etching with HF, it is advantageous to provide etching accesses 8 in regions, in which layers made of silicon and/or materials resistant to HF are located, in order to be able to avoid undesirable or uncontrolled etchings within the layer system, as indicated in FIG. 29. The “footprints” of the pillars of first oxide sacrificial layer 2 in substrate 1, which have been removed by the gas phase etching process, are also apparent here.

It is further possible to form etching accesses 8 in such a way that a defined separation may be achieved between the area that is to be stress-decoupled and the surrounding region/substrate. In this case, for example, spring-like suspensions or springs 15 may be implemented similarly to the representations in FIGS. 18A, 18B and 19, via which the later released and stress-decoupled area is still connected to the surrounding substrate and via which, for example, electrical strip conductors 13 (see FIGS. 18A, 18B, 19) may also be guided.

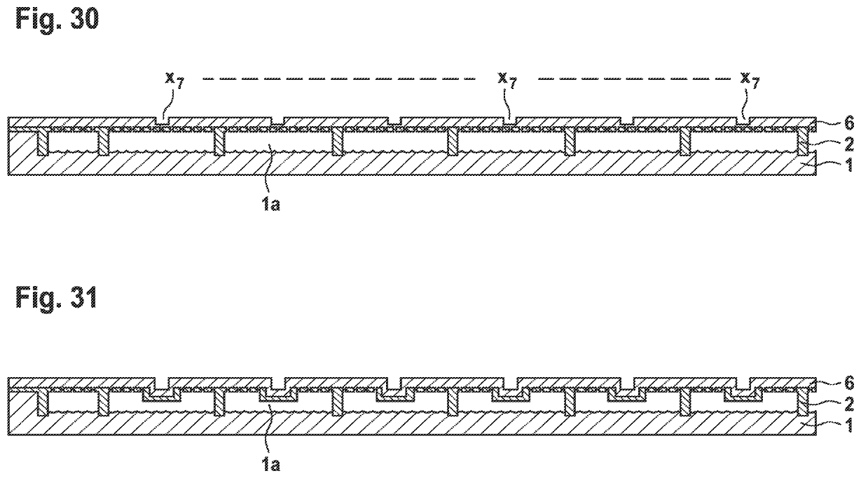

It is further also possible to provide nubs 9 at the underside and thus the side of the stress-decoupled area or carrier structure 3a, 3b facing substrate 1 including sensing area 20, in order to be able to preferably avoid a potential sticking of this area at substrate 1. To produce the nubs, indentations x₇ may be introduced into second oxide sacrificial layer 6 (closure oxide), as represented in FIG. 30, which are filled in later process steps with silicon. Alternatively, indentations may, however, also be etched into substrate 1, which are lined, for example, with first oxide sacrificial layer 2 and second oxide sacrificial layer 6 and filled in subsequent process steps with silicon, as indicated in FIG. 31. After the deposition of first oxide sacrificial layer 2, the production of openings x₃ also takes place here, through which substrate 1 may be etched. These openings x₃ may optionally also be located in the area of the indentations etched into substrate 1 (not shown).

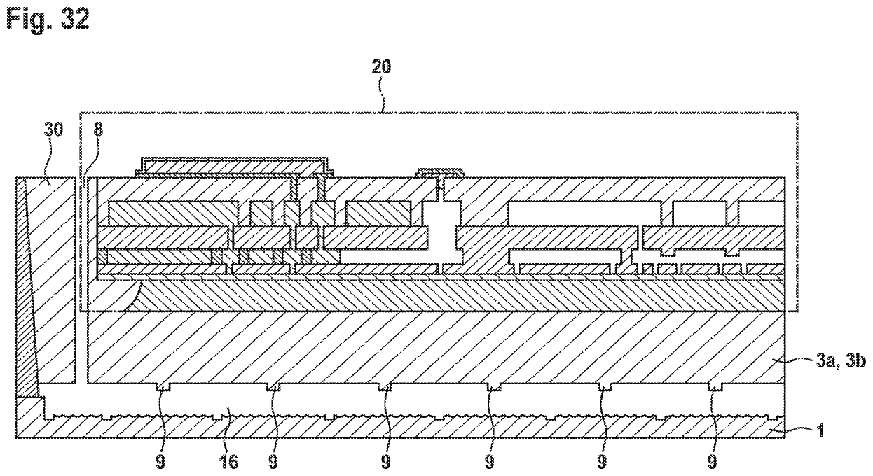

With both variations, it is possible in this way to implement nubs 9 made of polysilicon at the underside of the area to be stress-wise decoupled, as is apparent in FIG. 32.

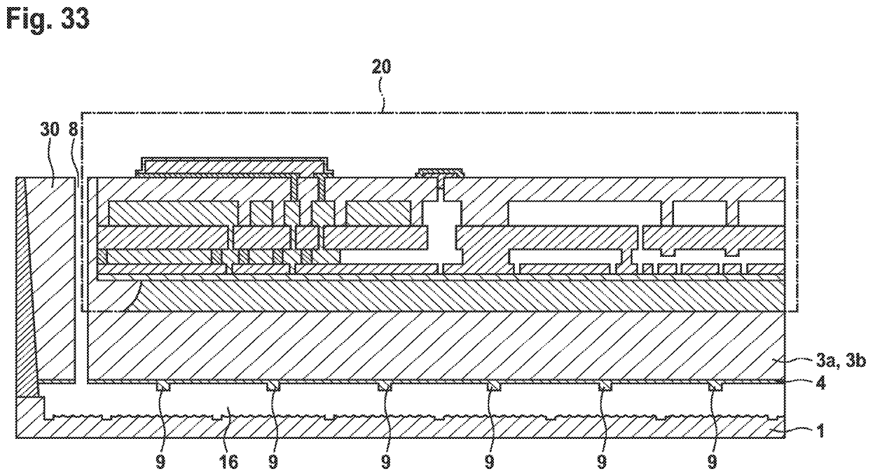

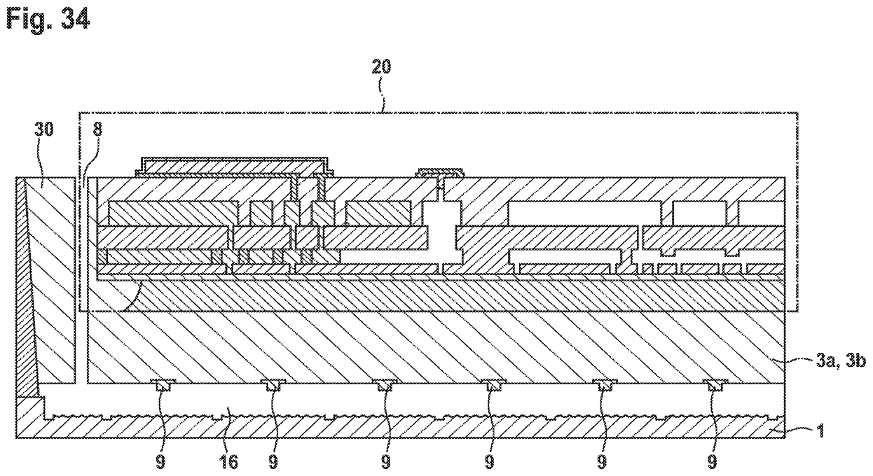

As is graphically indicated in the cross-sectional views of FIGS. 33 and 34, nubs 9 may also be made of or coated with an electrically insulating and etch-resistant material 4. For this purpose, the deposition of an electrically insulating layer, which is etch-resistant to HF in liquid or gaseous form, must take place after the deposition of second oxide sacrificial layer 6 and its optional structuring. For this purpose, silicon-rich silicon nitride has proven reliable. The use of layers made of aluminum oxide or silicon carbide or combinations of the mentioned materials is also possible.

It is equally possible, as represented in FIG. 34, that insulating layer 4 may be structured and may be located only in the area of nubs 9.

It is further also possible that the stress-decoupled area is connected via pillar-like structures or pillars 12 of arbitrary shape to substrate 1. The pillar-like structures or pillars 12 are connected here directly to the underside of carrier structure 3a, 3b and to the upper side of substrate 1. The structure of pillar-like structures 12 is comparable to that of the nub structures or nubs 9. The number and position of the pillar-like structures in this case may, as also in the case of the nub structures, be arbitrarily selected and may be adapted to existing requirements. The material of the pillar structures may include silicon, silicon oxide, silicon nitride, silicon-rich silicon nitride, aluminum oxide, silicon carbide or a combination of the mentioned materials. When selecting the material or when selecting the material combinations, it should be noted, however, that the material that comes into contact with the etching medium for removing oxide sacrificial layer 2, 6 exhibits a high etching resistance to the etching medium.

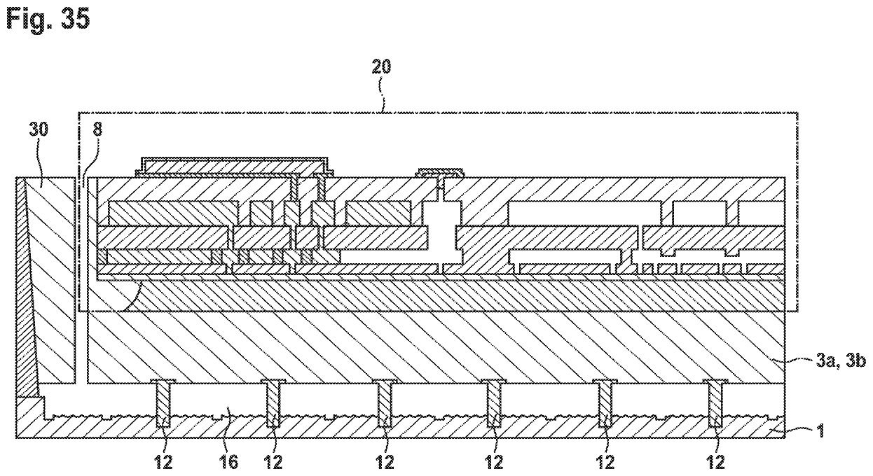

Material of the pillar-like structures may also be located extensively on the underside of stress-decoupled sensing area 20 and, here in particular, on the underside of carrier structure 3a, 3b or may be structured in such a way that it is located only in the area of the pillar-like structures, as indicated in FIG. 35.

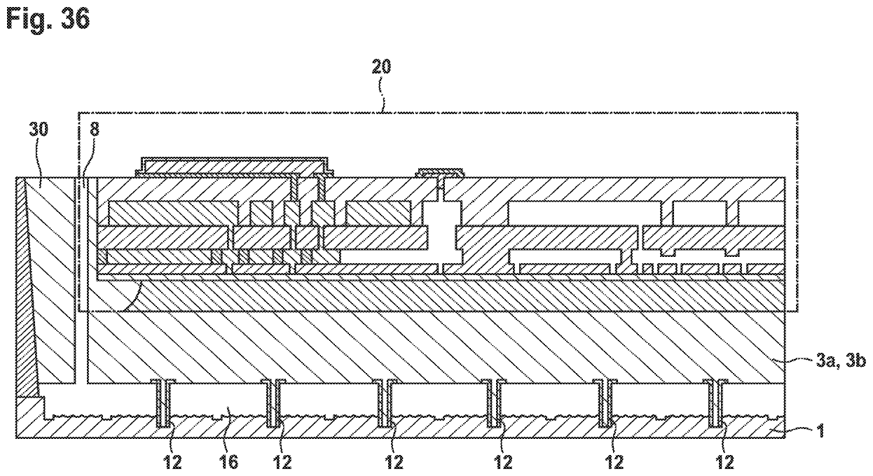

Several examples of further possible pillar-like structures 12 are represented in FIGS. 36 through 39. Pillar-like structures 12 are apparent in FIG. 36, which may include a coat made of a material that is electrically insulating and etch-resistant to the etching medium of oxide sacrificial layers 2, 6 such as, for example, silicon-rich silicon nitride, and a core made of polysilicon.

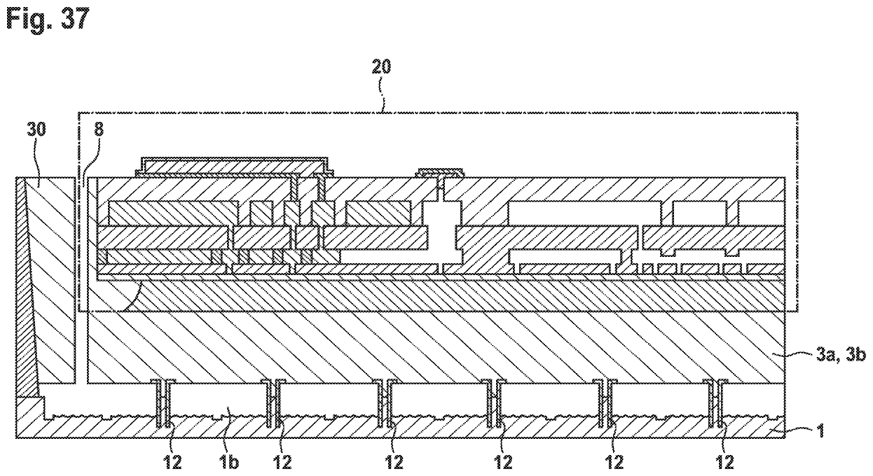

FIG. 37 shows an example of a pillar-like structure 12 including a core made of polycrystalline and monocrystalline silicon, which is formed from material of carrier structure 1 and from material of substrate 1.

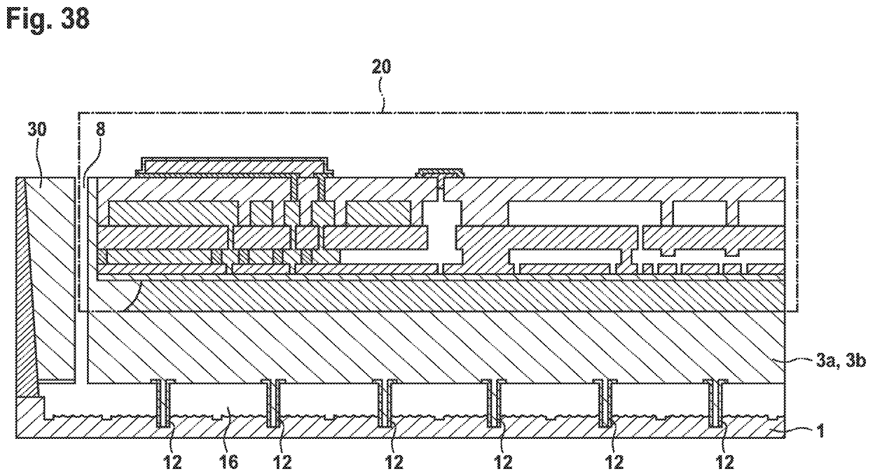

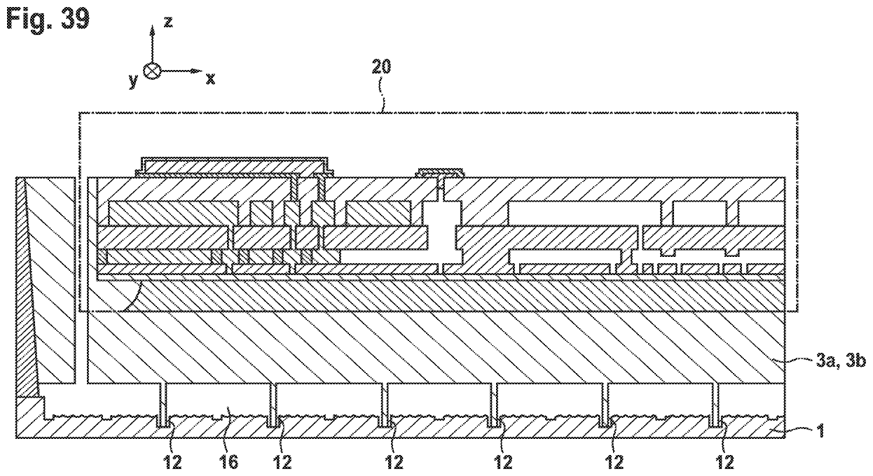

FIG. 38 shows a variant of pillar-like structures 12 including a polycrystalline silicon core made of material of carrier structure 1, which is connected electrically and mechanically to substrate 1 at the bottom of pillar-like structures 12, and FIG. 39 shows a variant, in which the coat made of electrically insulating material, for example, SiO₂, has been removed from pillar-like structure 12 and only the core made of silicon is still present.

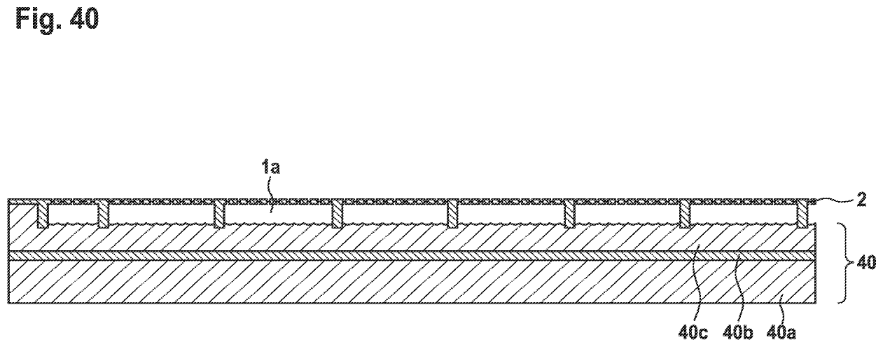

As is apparent in FIG. 40, it is also possible to provide an SOI (silicon on isolator) wafer 40 as the substrate material, which includes a monocrystalline silicon substrate 40a, an electrically insulating layer 40b (for example, SiO₂) situated above that and a monocrystalline or polycrystalline silicon layer 40c situated on the latter, the described method being capable of being carried out with SOI wafer 40. When using an SOI wafer, trench structures 1b are advantageously able to fully penetrate silicon layer 40c and insulating layer 40b may be used as an etch stop layer for the etching process (for example, trench etching process) (not shown). When using trench structures 1b as lateral etch stop structures, which are backfilled and closed with first oxide sacrificial layer 2, areas in substrate 1 may thus be defined, from which the substrate material may be removed without undercutting trench structures 1b within this area.

Since insulating layer 40c as well as the lateral etch stop structures may be designed here to be etch-resistant to a silicon etching process, substrate 1 may be etched using an etching process on which no high demands must be placed, for example, with respect to the anisotropic etching behavior. In order to avoid an uncontrolled lateral etching of insulating layer 40b and thus an undercutting of silicon layer 40c during the later oxide sacrificial layer etching, insulating layer 40b may be structured prior to the deposition/application of silicon layer 40c in such a way that material of silicon layer 40c on monocrystalline silicon substrate 40a is deposited in openings of insulating layer 40b and may thus act as a lateral etch stop. After the deposition of silicon layer 40c, a planarization step may further be carried out for producing a planar surface.

In one alternative variant, an indentation is initially produced in silicon substrate 40a, which is filled with insulating layer 40b. The deposited layer thickness of insulating layer 40b in this case is advantageously selected to be greater than the stripped layer thickness in the indentation of silicon substrate 40a. The surface is subsequently stripped by a planarization step in such a way that insulating layer 40b is located only in the indentations in the silicon substrate and a planar surface is produced. In a subsequent deposition process, silicon layer 40c is deposited onto the planarized surface and islands laterally separated from one another are formed from the material of insulating layer 40c. Areas in which silicon layer 40c comes into contact with silicon substrate 40a may also be used here as a lateral etch boundary.

In one further variant, the islands made of insulating layer 40b separated from one another are formed with the aid of a LOCOS process. By using a planarization step with which the nitride mask may also be removed for producing the local SiO₂ areas, it is also possible here to produce a planar surface with SiO₂ areas separated from one another. All of the aforementioned examples are understood to be exemplary and may be modified and/or combined in a variety of ways. Furthermore, the elastic structures and the manner of suspension of the sensing area may be arbitrarily selected and adapted to the respective particular application.

The stress-decoupled variants shown are advantageously not limited only to pressure sensors, but may also be used in other, stress-sensitive sensors such as, for example, micromechanical inertial sensors or in temperature sensors. The present invention may advantageously be applied to all types of micromechanical sensors, in which a stress decoupling of the sensing area is to be implemented. By this means, influences on the sensor signal resulting from the assembly and packaging technology (APT) may be reduced or avoided and cost-intensive superstructures for reducing the stress input may be omitted or reduced.

Only rough process steps are cited above. Those skilled in the art may thus draw conclusions about necessary process details based on the disclosure herein and on his/her technical expertise. In or after the described sequences, additional CMP steps may, if necessary, further also be carried out in order to produce surfaces on which further process steps or process sequences are implementable using standard semiconductor methods.

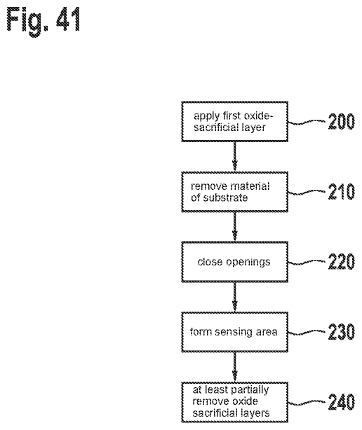

FIG. 41 shows in a basic manner a sequence of a method for manufacturing a provided micromechanical sensor 100.

In a step 200, an application of a first oxide-sacrificial layer 2 is carried out on a substrate 1.

In a step 210, a removal of material of substrate 1 through openings x₃ in first oxide sacrificial layer 2 is carried out.

In a step 220, a closing of openings X₃ in first oxide sacrificial layer 2 is carried out by applying a second oxide sacrificial layer 6.

In a step 230, a formation of a sensing area 20 on a carrier structure 3a, 3b is carried out, the sensing area 20 and carrier structure 3a, 3b being formed on oxide sacrificial layers 2, 6 and sensing area 20 and/or carrier structure 3a, 3b being connected to substrate 1 via at least one attachment area 30, which forms a flexible structure 15.

In a step 240, an at least partial removal of oxide sacrificial layers 2, 6 between carrier structure 3a, 3b and substrate 1 is carried out with the aid of an etching process.

1-15. (canceled)

16. A method for manufacturing a micromechanical sensor, comprising the following steps:
applying a first oxide sacrificial layer onto a substrate;
removing material of substrate through openings in the first oxide sacrificial layer;
closing the openings in the first oxide sacrificial layer by applying a second oxide sacrificial layer;
forming a sensing area on a carrier structure, the sensing area and the carrier structure being formed on the first and second oxide sacrificial layers and the sensing area and/or the carrier structure being connected to the substrate via at least one attachment area, which forms a flexible structure; and
at least partially removing the first and second oxide sacrificial layers between the carrier structure and the substrate using an etching process.

17. The method as recited in claim 16, wherein trenches and/or trench structures are formed in the substrate for removing the first sand second oxide sacrificial layers between the carrier structure and the substrate.

18. The method as recited in claim 17, wherein support structures in the form of the trenches and/or the trench structures in the substrate are filled with the first oxide sacrificial layer and serve as support for the carrier structure in further steps of the manufacturing method.

19. The method as recited in claim 18, wherein the etching process for producing the trenches and/or the trench structures as etching channels and/or the support structures for supporting a carrier structure in the substrate is an isotropic or anisotropic process.

20. The method as recited in claim 17, wherein to form the trenches, a partial removal of the substrate takes place below the first oxide sacrificial layer through openings in the first oxide sacrificial layer, and the openings in the first oxide sacrificial layer are closed by applying the second oxide sacrificial layer.

21. The method as recited in claim 16, wherein nubs are formed at the carrier structure oriented toward the substrate and/or nubs are formed at the substrate oriented toward the carrier structure.

22. The method as recited in claim 16, wherein pillars are formed on the carrier structure oriented toward the substrate.

23. The method as recited in claim 22, wherein the pillars are formed connected to the substrate or spaced apart from the substrate.

24. The method as recited in claim 16, wherein a first polysilicon layer having a defined layer thickness is formed on the first and second oxide sacrificial layers.

25. The method as recited in claim 24, wherein a second polysilicon layer having a defined layer thickness is formed as the carrier structure on the first polysilicon layer.

26. The method as recited in claim 24, wherein an etch-resistant layer is formed at a side of the first polysilicon layer oriented toward the substrate.

27. The method as recited in claim 22, wherein the attachment area of the carrier structure to the substrate is formed at least partially and/or in sections in a monocrystalline manner.

28. The method as recited in claim 22, wherein the attachment area of the carrier structure to the substrate is formed in a polycrystalline manner.

29. The method as recited in claim 27, wherein electrical circuit components are formed in the attachment area, which are attached with strip conductors to the sensing area.

30. A micromechanical sensor, comprising:
a carrier structure including a sensing area formed on a carrier structure, the carrier structure being spaced apart at least partially from the substrate downwardly and being attached laterally at least in sections to the substrate.
